(19) United States
(12) Patent Application Publication
(10) Pub. No.: US 2013/0026435 A1
(43) Pub. Date: Jan. 31, 2013

(54) SWITCHING DEVICE AND RESISTANCE CHANGE MEMORY DEVICE USING THE SAME

(71) Applicants: Jae-Yun Yi, Gyeonggi-do (KR); Sung-Woong Chung, Gyeonggi-do (KR); Yun-Taek Hwang, Gyeonggi-do (KR); Hyun-Sang Hwang, Gwangju (KR); Ju-Bong Park, Gwangju (KR)

(72) Inventors: Jae-Yun Yi, Gyeonggi-do (KR); Sung-Woong Chung, Gyeonggi-do (KR); Yun-Taek Hwang, Gyeonggi-do (KR); Hyun-Sang Hwang, Gwangju (KR); Ju-Bong Park, Gwangju (KR)

(21) Appl. No.: 13/333,591

(22) Filed: Dec. 21, 2011

(30) Foreign Application Priority Data
Jul. 26, 2011 (KR) 10-2011-0074216

(51) Int. Cl. H01L 45/00

(52) U.S. Cl. 257/2; 257/E45.002

(57) ABSTRACT

A switching device that provides bipolar current paths and a resistance change memory device using the switching device. The switching device includes a first electrode, a second electrode, and an amorphous carbon layer interposed between the first electrode and the second electrode and configured to control a bipolar current to flow therethrough in response to a voltage applied between the first electrode and the second electrode.

### CROSS-REFERENCE TO RELATED APPLICATIONS

The present application claims priority of Korean Patent Application No. 10-2011-0074216, filed on Jul. 26, 2011, which is incorporated herein by reference in its entirety.

### BACKGROUND

1. Field

Exemplary embodiments of the present invention relate to a switching device and a resistance change memory device using the switching device, and more particularly, to a switching device that provides bipolar current paths, and a resistance change memory device using the switching device.

2. Description of the Related Art

A resistance change memory device is a device for storing data based on the principle that a variable resistor has different resistance states in response to a bias applied thereto. The resistor includes a transition metal oxide or a perovskite-based material.

Resistance change memory devices are divided into two types depending on switching characteristics. One is a unipolar-mode resistance change memory device where a set/reset operation is performed at one polarity, and the other is a bipolar-mode resistance change memory device where a set/reset operation is performed at different polarities. Since the bipolar-mode resistance change memory device which performs a switching operation in a bipolar mode has diverse advantages, such as uniform switching characteristics and small reset current consumption as it performs a reset operation through an electric field, it is being developed in various manners.

Meanwhile, in order to increase the integration degree of a resistance change memory device, a so-called cross-point structure is developed. The cross-point structure includes a plurality of first conductive lines, a plurality of second conductive lines crossing the first conductive lines, and resistors between the first conductive lines and the second conductive lines, wherein the resistor is disposed at every cross-point between the first conductive lines and the second conductive lines.

Since the resistors are substantially coupled with each other through the first conductive lines and the second conductive lines in the cross-point structure, there may be generated between memory cells inter-cell interference and leakage current. Therefore, a selection device through which current hardly flow at a predetermined threshold voltage or less is interposed between the first conductive line and the second conductive line to be serially coupled with one end of a resistor. For example, diverse diodes, such as a P-N diode and a Schottky diode, are widely used as the selection device.

However, as mentioned above, the resistance change memory device that performs a switching operation in a bipolar mode operates at bipolarities. Therefore, when a diode providing a unipolar current path is used as the selection device, a reverse current is too low for the resistance change memory device to perform an operation.

Therefore, it is desirable to develop a selection device that may be used for a resistance change memory device that performs a switching operation in the bipolar mode.

### SUMMARY

An embodiment of the present invention is directed to a switching device that may provide bipolar current paths that are symmetrical to each other and may control the level of bipolar current appropriately.

Another embodiment of the present invention is directed to a resistance change memory device using the switching device as a selection device that is coupled with a resistor in a cross-point structure.

In accordance with an embodiment of the present invention, a switching device includes: a first electrode; a second electrode; and an amorphous carbon layer interposed between the first electrode and the second electrode and configured to control a bipolar current to flow therethrough in response to a voltage applied between the first electrode and the second electrode.

In accordance with another embodiment of the present invention, a resistance change memory device includes: a first electrode; a second electrode; a variable resistance material layer interposed between the first electrode and the second electrode and configured to switch between different resistance states in response to a first voltage applied between both ends of the variable resistance material layer; and an amorphous carbon layer interposed between the variable resistance material layer and the first electrode or between the variable resistance material layer and the second electrode and configured to control a bipolar current to flow therethrough in response to a second voltage applied between both ends of the amorphous carbon layer.

In accordance with yet another embodiment of the present invention, a data processing system includes: a memory; and a processor configured to process data with the memory, wherein the memory includes: a first electrode; a second electrode; a variable resistance material layer interposed between the first electrode and the second electrode and configured to switch between different resistance states in response to a first voltage applied between both ends of the variable resistance material layer; and an amorphous carbon layer interposed between the variable resistance material layer and the first electrode or between the variable resistance material layer and the second electrode and configured to control a bipolar current to flow therethrough in response to a second voltage applied between both ends of the amorphous carbon layer.

### BRIEF DESCRIPTION OF THE DRAWINGS

FIG. 1 is a cross-sectional view illustrating a switching device in accordance with an embodiment of the present invention.

FIG. 2 illustrates the current-voltage characteristics of the switching device shown in FIG. 1.

FIGS. 3 to 6 illustrate the current-voltage characteristics of the switching device shown in FIG. 1 according to diverse factors.

FIG. 7 illustrates the durability of the switching device shown in FIG. 1.

FIG. 8 is a cross-sectional view illustrating a resistance change memory device in accordance with a first embodiment of the present invention.

FIG. 9 illustrates the current-voltage characteristics of the resistance change memory device shown in FIG. 8.

FIG. 10 is a cross-sectional view illustrating a resistance change memory device in accordance with a second embodiment of the present invention.

FIG. 11 illustrates the current-voltage characteristics of the resistance change memory device shown in FIG. 10.

FIG. 12 is a perspective view illustrating a cross-point structure of the resistance change memory device shown in FIG. 10.

FIG. 13 illustrates a processor system in accordance with an embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

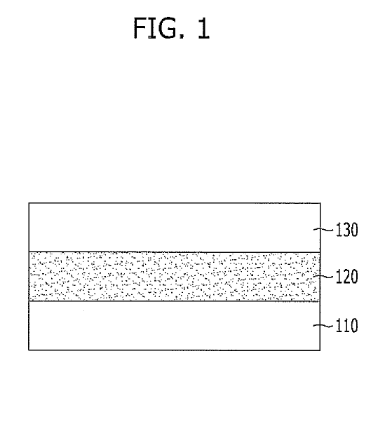

Hereafter, a switching device in accordance with an embodiment of the present invention is described with reference to FIGS. 1 to 7.

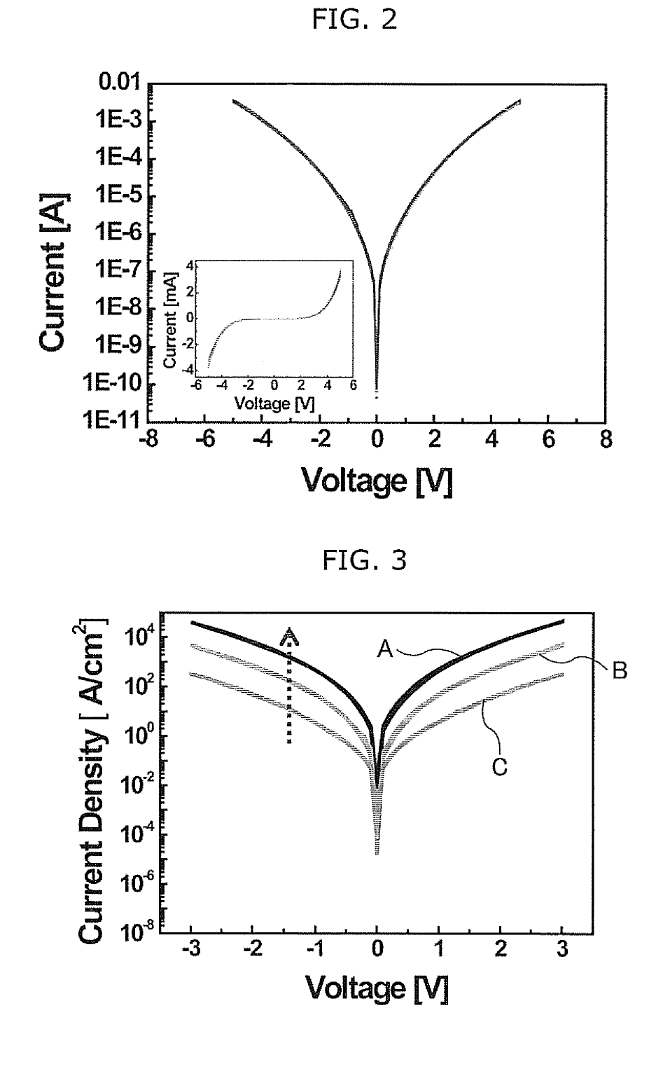

FIG. 1 is a cross-sectional view illustrating a switching device in accordance with an embodiment of the present invention, and FIG. 2 illustrates the current-voltage characteristics of the switching device shown in FIG. 1.

Referring to FIG. 1, the switching device in accordance with the embodiment of the present invention includes a first electrode 110, a second electrode 130, and an amorphous carbon layer 120 interposed between the first electrode 110 and the second electrode 130.

The first electrode 110 and the second electrode 130 are formed of conductive materials, which are metal, such as platinum (Pt), tungsten (W), aluminum (Al), copper (Cu), tantalum (Ta), or metal nitride, such as a titanium nitride (TiN) and a tantalum nitride (TaN).

Here, bipolar current flows through the amorphous carbon layer 120 in opposite directions in response to a voltage applied to the first electrode 110 and the second electrode 130. To be specific, when a predetermined positive voltage is applied between the first electrode 110 and the second electrode 130, a current flows in a first direction through the amorphous carbon layer 120, and when a predetermined negative voltage is applied between the first electrode 110 and the second electrode 130, a current flows in a second direction that is opposite to the first direction through the amorphous carbon layer 120. The same level of the current flows through the amorphous carbon layer 120, but in opposite directions, in response to the same levels, i.e., the same absolute values of the positive voltage and the negative voltage. This is a fact that is experimentally proven, and this is described hereafter in detail with reference to FIG. 2.

FIG. 2 is a graph showing current-voltage characteristics when platinum (Pt) is used for the first electrode 110 and tungsten (W) is used for the second electrode 130. In particular, the big box represents a current in a log scale, and the small box in the big box represents a substantive current.

Referring to FIG. 2, when the voltage between the first electrode 110 and the second electrode 130 is increased in the positive direction from approximately 0V, the current flowing in the first direction is increased as well. When the voltage between the first electrode 110 and the second electrode 130 is increased in the negative direction from approximately 0V, the current flowing in the opposite direction to the first direction is increased as well. It may be understood that the current flowing in the first direction and the current flowing in the opposite direction to the first direction are symmetrical at the same level of voltages. Particularly, when the voltage between the first electrode 110 and the second electrode 130 is increased from approximately 0V to approximately 2V or approximately −2V, almost no current flows, and when the voltage is increased to approximately 2V or approximately −2V or more, the level of the current is increased drastically.

As described above, the resistance change memory device having a cross-point structure may use a selection device, and in particular, a resistance change memory device which performs a switching operation in a bipolar mode is to use a selection device that may provide symmetrical bipolar current paths to secure uniform set/reset characteristics. Moreover, a current as low as pA to nA units flows through the selection device at a voltage level lower than a predetermined voltage (e.g., ½ Vread lower than a read voltage Vread which is applied to a selected cell in the cross-point structure), while a relatively high current of approximately μA and mA units flows through the selection device at a voltage level equal to or higher than the predetermined voltage (such as the read voltage Vread), which will be described later.

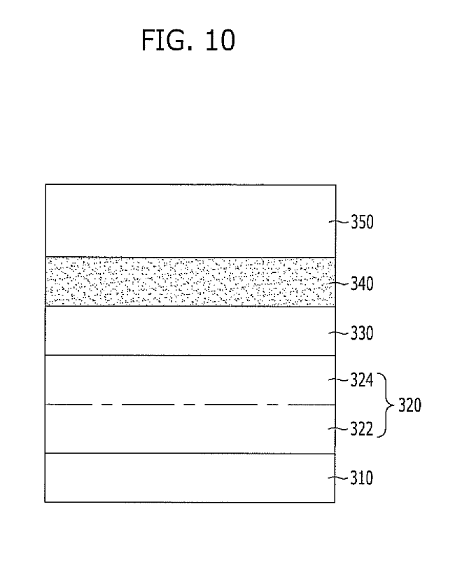

Therefore, the switching device of FIG. 1, in particular, the amorphous carbon layer 120 is appropriate to be used as a selection device for a resistance change memory device that is realized in a cross-point structure and performs a switching operation in a bipolar mode. This will be described below in detail with reference to FIGS. 10 to 12. However, it should be noted that the scope and concept of the present invention are not limited to it, and the amorphous carbon layer 120 of FIG. 1 may be used as a selection device in a resistance change memory device that performs a switching operation in a unipolar mode or resistance change memory devices of various structures.

Meanwhile, the level of the current is to be controlled at an appropriate level to use the amorphous carbon layer 120 of FIG. 1 as a selection device of a resistance change memory device. Since the specific range of the current level may be diversely modified in consideration of the kind and characteristics of a resistance change material layer, which is to be described later, it is not described in the present specification. A method of controlling the current level of the switching device shown in FIG. 1 is described in accordance with the embodiment of the present invention.

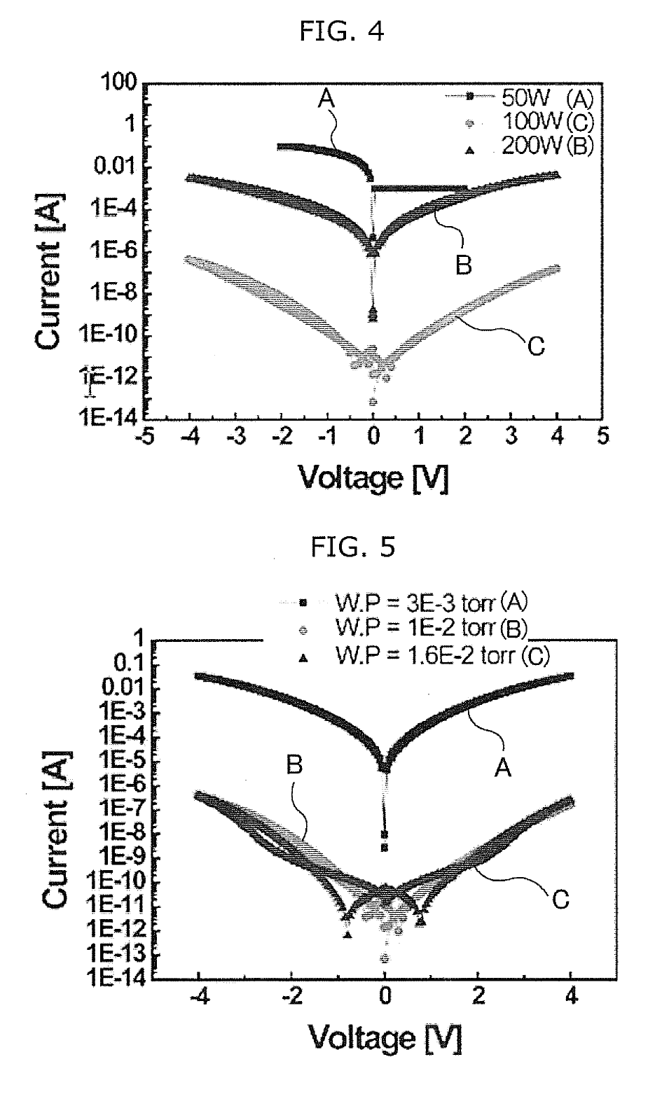

FIGS. 3 to 6 illustrate the variation in the current-voltage characteristics of the switching device shown in FIG. 1 by controlling various factors. In particular, FIG. 3 shows the variation depending on the thickness of the amorphous carbon layer 120 shown in FIG. 1, and FIG. 4 shows the variation depending on the power applied when the amorphous carbon layer 120 is deposited. FIG. 5 shows the variation depending on the pressure applied when the amorphous carbon layer 120 is deposited, and FIG. 6 shows the variation depending on the temperature applied when the amorphous carbon layer 120 is deposited.

Referring to FIG. 3, the dotted line arrow represents the sequence of the current graphs, i.e., C→A, for the decreasing of the thickness of the amorphous carbon layer 120. As the thickness of the amorphous carbon layer 120 decreases, current density increases. Therefore, the level of a bipolar current may be controlled by controlling the thickness of the amorphous carbon layer 120.

Referring to FIG. 4, the level of current is changed depending on the amplitude of the power applied when the amorphous carbon layer 120 is deposited. Therefore, the level of the bipolar current may be controlled by controlling the applied power during the deposition of the amorphous carbon layer 120.

Referring to FIG. 5, the level of current is increased with the decrease of the pressure applied when the amorphous carbon layer 120 is deposited. Therefore, the level of the bipolar current may be controlled controlling the applied pressure during the deposition of the amorphous carbon layer 120.

Referring to FIG. 6, the level of current is increased as the temperature increases when the amorphous carbon layer 120 is deposited. Therefore, the level of the bipolar current may be controlled by controlling the temperature during the deposition of the amorphous carbon layer 120.

After all, the level of the bipolar current flowing through the amorphous carbon layer 120 may be controlled by controlling at least one among the thickness of the amorphous carbon layer 120, the power, pressure, and temperature applied during the deposition of the amorphous carbon layer 120.

Furthermore, although not illustrated in the drawing, the amorphous carbon layer 120 may include sp² and sp³ hybridized carbon. The level of bipolar current may be controlled by controlling the relative ratio of sp² and sp³.

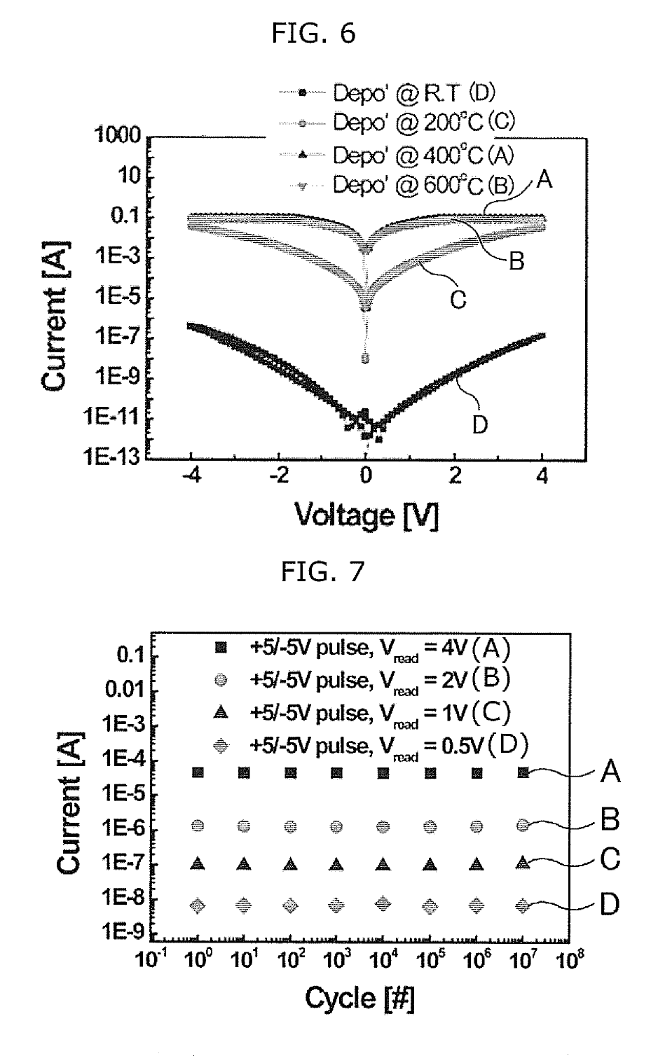

Also, the amorphous carbon layer 120 shown in FIG. 1 is to meet the durability conditions to be used as the selection device of the resistance change memory device. A resistance change memory device performs numerous times of set/reset operations and accordingly, set/reset voltages are repeated applied to the selection device in numerous times as well. This is described below with reference to FIG. 7.

FIG. 7 illustrates the durability of the switching device shown in FIG. 1.

Referring to FIG. 7, when pulses of approximately +5V/−5V are consecutively applied to the switching device shown in FIG. 1 up to 10⁷ times, the current level is maintained uniformly at the read voltages Vread of approximately 4V, 2V, 1V and 0.5V. Therefore, it may be seen that the switching device shown in FIG. 1 has the durability for a resistance change memory device.

Up until now, the switching device in accordance with the embodiment of the present invention and the characteristics of the switching device has been described. The switching device in accordance with the embodiment of the present invention has appropriate characteristics to be used as the selection device of a resistance change memory device, and the resistance change memory device where the switching device may be used as the selection device is described first, hereafter.

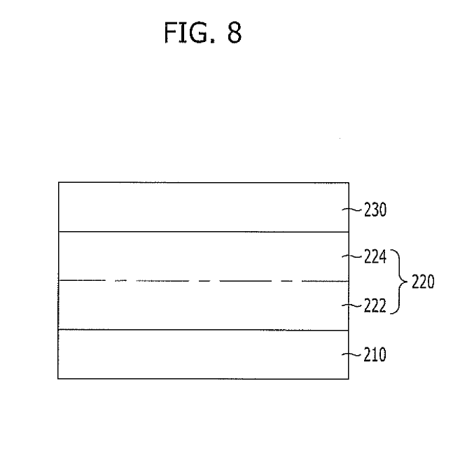

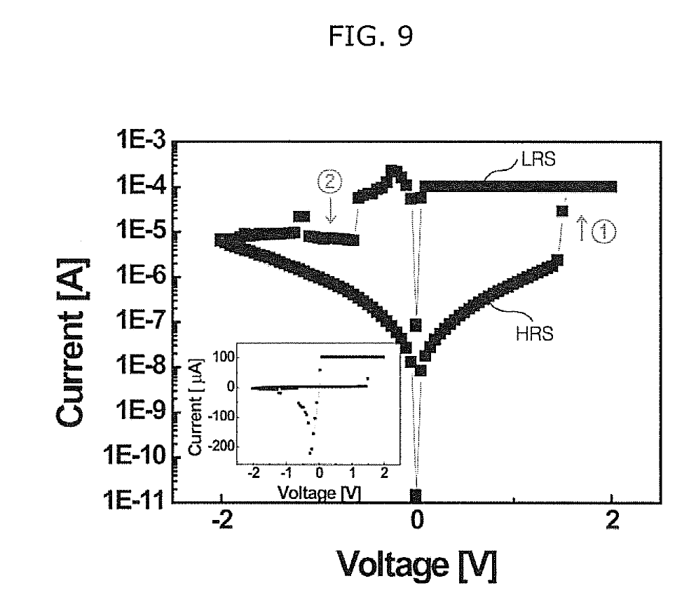

FIG. 8 is a cross-sectional view illustrating a resistance change memory device in accordance with a first embodiment of the present invention, and FIG. 9 illustrates the current-voltage characteristics of the resistance change memory device shown in FIG. 8. Here, FIGS. 8 and 9 show an example of a resistance change memory device which includes a variable resistance material layer and does not include a selection device to be combined with the variable resistance material layer. In short, a variable resistance material layer forms a unit cell without a selection device.

Referring to FIG. 8, the resistance change memory device shown in the first embodiment of the present invention includes a first electrode 210, a second electrode 230, and a variable resistance material layer 220 interposed between the first electrode 210 and the second electrode 230.

The first electrode 210 and the second electrode 230 are formed of a conductive material respectively, such as metal or metal nitride.

The variable resistance material layer 220 may be formed of transition metal oxide, such as oxide of any one selected from the group consisting of tantalum (Ta), nickel (Ni), titanium (Ti), iron (Fe), cobalt (Co), manganese (Mn), and tungsten (W), or a perovskite-based material. However, the concept and scope of the present invention is not limited to it, and the variable resistance material layer 220 is a material that may switch between different resistance states in response to a voltage applied to both ends of the variable resistance material layer 220.

In particular, the resistance change memory device shown in FIG. 8 may be a variable resistance memory device that operates in a bipolar mode. To be specific, the voltage polarity applied during a set operation where the resistance state of the variable resistance material layer 220 is changed from a high resistance state (HRS) to a low resistance state (LRS) and the voltage polarity applied during a reset operation where the resistance state of the resistance variable material layer 220 is changed from a low resistance state (LRS) to a high resistance state (HRS) may be different. For the variable resistance material layer 220 of the resistance change memory device that operates in the bipolar mode, diverse transition metal oxides, such as oxide of any one selected from the group consisting of tantalum (Ta), nickel (Ni), titanium (Ti), iron (Fe), cobalt (Co), manganese (Mn), and tungsten (W), or a perovskite-based material may be used. In this embodiment of the present invention, a structure where an amorphous carbon layer 222 and a metal-containing layer 224 are stacked is used as the variable resistance material layer 220. The fact that the stacked structure of the amorphous carbon layer 222 and the metal-containing layer 224 may operate in the bipolar mode in response to a voltage applied to both ends of the stacked structure is already disclosed in U.S. Pat. No. 7,220,982, and it is proven experimentally. This is described in detail with reference to FIG. 9.

FIG. 9 is a graph showing the current-voltage characteristics of a resistance change memory device using platinum (Pt) for the first electrode 210, tungsten (W) for the second electrode 230, and a stacked structure of an amorphous carbon layer and a copper layer as the variable resistance material layer 220.

Referring to FIG. 9, when the voltage between the first electrode 210 and the second electrode 230 is increased in a positive direction from approximately 0V in the initial stage, a set operation (refer to an arrow \textcircled{1}) where the resistance state of the variable resistance material layer 220 is changed from a high resistance state (HRS) to a low resistance state (LRS) at a predetermined voltage is performed. Hereafter, the voltage applied during a set operation is referred to as a set voltage.

Subsequently, when the voltage applied to the variable resistance material layer 220 is decreased to approximately 0V, the low resistance state (LRS) of the variable resistance material layer 220 is maintained and then when the voltage is increased in the negative direction from approximately 0V, a reset operation (refer to an arrow \textcircled{2}) where the resistance state of the variable resistance material layer 220 is changed from a low resistance state (LRS) to a high resistance state (HRS) at a predetermined voltage is performed. Hereafter, the voltage applied during a reset operation is referred to as a reset voltage.

Since the polarities of the set voltage and the reset voltage are different, it may be seen that the resistance change memory devices shown in FIGS. 8 and 9 perform a switching operation in the bipolar mode.

When the resistance change memory devices shown in FIGS. 8 and 9 are realized in a cross-point structure, that is, when the variable resistance material layer 220 is disposed as a unit cell at every cross-point, i.e., intersection between a plurality of first conductive lines and a plurality of second conductive lines that are stretched in crossing directions, there are the following concerns.

When a read voltage Vread is applied to a selected cell, a lower voltage, e.g., ½ Vread, is applied to the unselected cells that share a conductive line with the selected cell. For example, when the read voltage Vread is a value between approximately 1V and approximately 2V, the value of ½ Vread becomes a value between approximately 0.5V and approximately 1V. The variable resistance material layer 220 is in a low resistance state (LRS) and a relatively high current flows through the variable resistance material layer 220 at the voltage of approximately 0.5V to approximately 1V. Therefore, current may leak toward the unselected cells that are in the low resistance state (LRS) among the unselected cells to which the ½ Vread is applied, and as a result, a sensing error may occur. Therefore, the above-mentioned selection device may be further included to realize the cross-point structure.

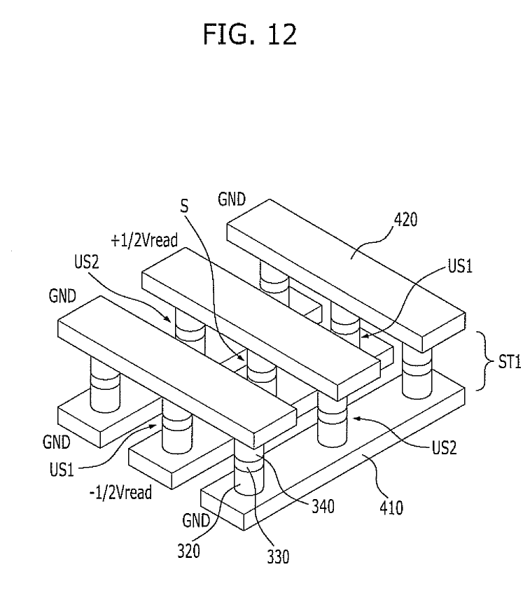

Hereafter, a resistance change memory device including a variable resistance material layer and a selection device as a unit cell and the characteristics of the resistance change memory device are described with reference to FIGS. 10 and 12.

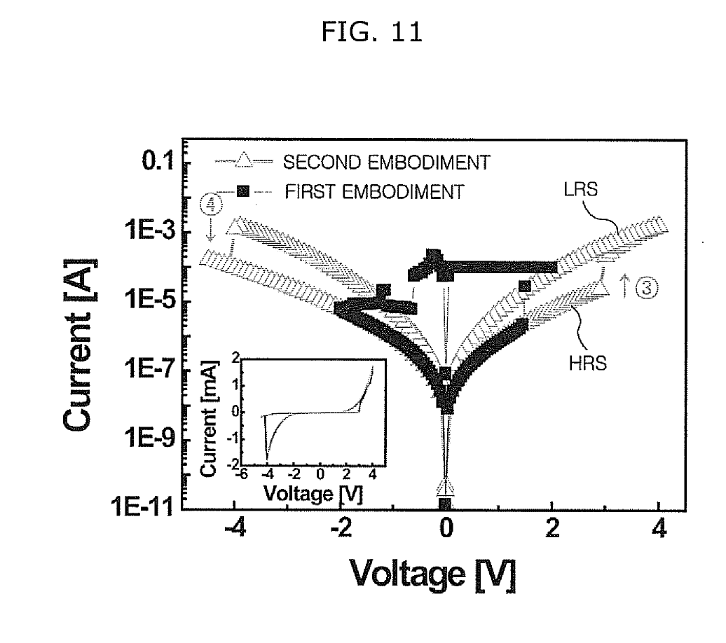

FIG. 10 is a cross-sectional view illustrating a resistance change memory device in accordance with a second embodiment of the present invention, and FIG. 11 illustrates current-voltage characteristics of the resistance change memory device shown in FIG. 10.

Referring to FIG. 10, the resistance change memory device in accordance with the second embodiment of the present invention includes a first electrode 310, a second electrode 350, and a unit cell interposed between the first electrode 310 and the second electrode 350 and including a variable resistance material layer 320 and an amorphous carbon layer 340, which is a second amorphous carbon layer 340, stacked therein.

The first electrode 310 and the second electrode 350 are formed of a conductive material, respectively, such as metal or metal nitride.

The variable resistance material layer 320 is substantially the same as the above-described variable resistance material layer 220 of FIG. 8. For example, the resistance variable material layer 320 may be of a stacked structure of a first amorphous carbon layer 322 and a metal containing layer 324.

The second amorphous carbon layer 340 is substantially the same as the above-described amorphous carbon layer 120 shown in FIG. 2, and it may substantially function as a selection device in the resistance change memory device in accordance with the second embodiment of the present invention.

Meanwhile, although the present embodiment shows a case where an intermediate layer 330 that may enhance the interface characteristics is interposed between the variable resistance material layer 320 and the second amorphous carbon layer 340, the scope and concept of the present invention are not limited to it and the intermediate layer 330 may be omitted. The intermediate layer 330 may be formed of a metal material such as tungsten (W). Also, although the present embodiment shows a case where the variable resistance material layer 320 is disposed in the lower part and the second amorphous carbon layer 340 is disposed over the variable resistance material layer 320, the scope and concept of the present invention are not limited to it and the upper and lower positions may be switched.

Hereafter, the current-voltage characteristics of a resistance change memory device, where the variable resistance material layer 320 and the second amorphous carbon layer 340 which is a selection device coupled with the variable resistance material layer 320 are interposed as a unit cell between the first electrode 310 and the second electrode 350, are described with reference to FIG. 11.

FIG. 11 is a graph showing the current-voltage characteristics of a resistance change memory device using platinum (Pt) for the first electrode 310, tungsten (W) for the second electrode 350, a stacked structure of an amorphous carbon layer and a copper layer as the variable resistance material layer 320, and tungsten (W) for the intermediate layer 330. Here, a curve marked with Δ represents the current-voltage characteristics of the resistance change memory device in accordance with the second embodiment of the present invention. For the description purpose, the current-voltage characteristics of the resistance change memory device in accordance with the above-described first embodiment (refer to FIGS. 8 and 9) of the present invention is represented with a curve marked with ▪.

Referring to FIG. 11, when the voltage between the first electrode 310 and the second electrode 350 is increased in the positive direction from approximately 0V, a set operation (refer to an arrow \textcircled{3}) where the resistance state of the unit cell is changed from a high resistance state (HRS) to a low resistance state (LRS) at a predetermined set voltage is performed. Here, it may be seen that the set voltage is increased, compared to the set voltage of the first embodiment.

Subsequently, when the voltage is decreased to approximately 0V and then increased in the negative direction, the unit cell is maintained at a low resistance state (LRS) and then a reset operation (refer to an arrow \textcircled{4}) where the resistance state is changed from a low resistance state (LRS) to a high resistance state (HRS) at a predetermined reset voltage is performed. Here, it may be seen that the reset voltage is increased, compared to the reset voltage of the first embodiment.

When the set voltage and the reset voltage increase, it becomes favorable for securing a read operation margin. Also, it may be understood in the present embodiment that the set voltage and the reset voltage substantially have the same amplitude, and accordingly, uniform set/reset characteristics may be obtained.

Furthermore, since a period where almost no current flows increase relatively, for example, a voltage period between approximately −2V and approximately 2V, the occurrence of leakage current and the generation of a sensing error resulting from the leakage current may be prevented although in a cross-point structure. This is described, hereafter, with reference to FIG. 12.

FIG. 12 is a perspective view illustrating a cross-point structure of the resistance change memory device shown in FIG. 10.

Referring to FIG. 12, the cross-point structure includes a plurality of first conductive lines 410 that are in parallel to each other, a plurality of second conductive lines 420 that are disposed over the first conductive lines 410 and in parallel to each other while crossing the first conductive lines 410, and unit cells which includes a stack of the variable resistance material layer 320, the intermediate layer 330, and the amorphous carbon layer 340 and are disposed at the cross-points between the first conductive lines 410 and the second conductive lines 420.

Here, the first conductive lines 410 and the second conductive lines 420 are formed of the same materials as the first electrode 310 and the second electrode 350 shown in FIG. 10, respectively.

When a read operation is performed onto a selected cell S in the cross-point structure, voltages of approximately −½ Vread and approximately ½ Vread are applied to the first conductive lines 410 and the second conductive lines 420 that are coupled with the selected cell S and thus a read voltage Vread is applied between both ends of the selected cell S, and a ground voltage GND is applied to the other first conductive lines 410 and the second conductive lines 420 that are not coupled with the selected cell S. Here, −½ Vread is applied between both ends of the unselected cells US1 that are coupled with the first conductive line 410 also coupled with the selected cell S, and ½ Vread is applied between both ends of the unselected cells US2 that are coupled with the second conductive line 420 also coupled with the selected cell S.

Referring back to FIG. 11, for example, when the read voltage Vread is approximately 3V or approximately −3V, and accordingly, ½ Vread has a value of approximately 1.5V or approximately −1.5V, almost no current flows through the unit cell at the voltage of approximately 1.5V or approximately −1.5V although the unit cell is in a low resistance state (LRS). In short, although the unselected cells US1 and US2 are in the low resistance state (LRS), they do not become the path for leakage current.

In consequences, when an amorphous carbon layer is used as a selection device as illustrated in the second embodiment of the present invention, inter-cell interference and the occurrence of leakage current are decreased, compared with the first embodiment which does not use a selection device, and the resistance change memory device may operate in a cross-point structure.

Meanwhile, although the first embodiment shows a resistance change memory device having one stack ST1, the scope and concept of the present invention are not limited to it, and the resistance change memory device may have a multi-stacked structure where more than two stacks are vertically stacked. In this multi-stacked structure, a second stack (not shown) over the first stack ST1 may share the second conductive lines 420.

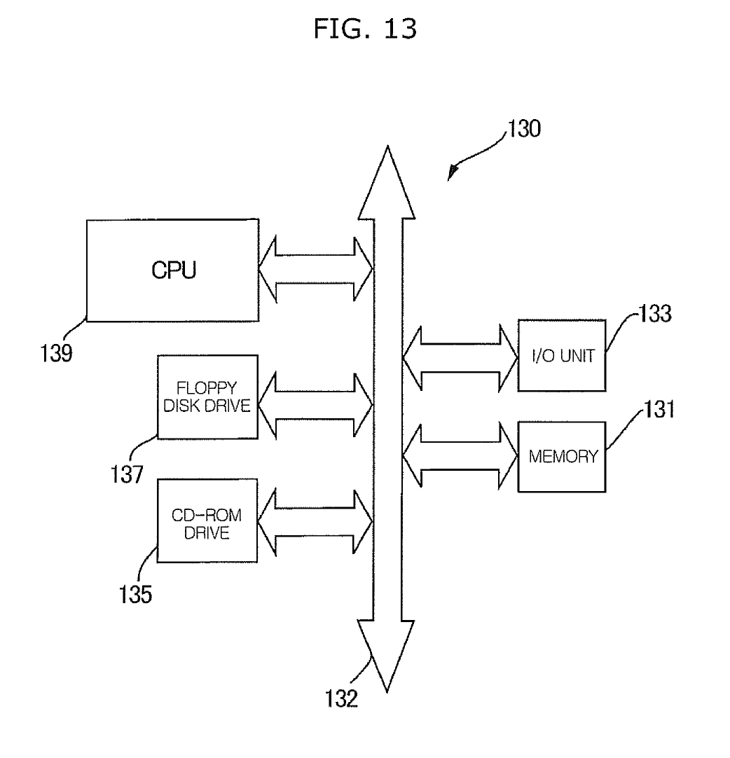

FIG. 13 illustrates a processor system in accordance with an embodiment of the present invention.

The processor system 130 includes a memory 131 that includes the structure illustrated in FIG. 10 or 12.

Besides, the processor system 130 may further include diverse constituent elements for processing, such as a central processing unit (CPU) 139, a floppy disk drive 137 and a CD-ROM drive 135 as peripheral circuit devices, and an input/output unit 133.

The memory 131 may communicate with the CPU 139 through a bus 132. The floppy disk drive 137, a CD-ROM drive 135, and an input/output unit 133 may communicate with the CPU 139 through the bus 132.

The switching device in accordance with an embodiment of the present invention may provide symmetrical bipolar current paths and control the level of bipolar current at an appropriate level.

Also, the resistance change memory device in accordance with an embodiment of the present invention may use the switching device as a selection device coupled with a resistor in a cross-point structure.

While the present invention has been described with respect to the specific embodiments, it will be apparent to those skilled in the art that various changes and modifications may be made without departing from the spirit and scope of the invention as defined in the following claims.

What is claimed is:

1. A switching device, comprising:
a first electrode;
a second electrode; and
an amorphous carbon layer interposed between the first electrode and the second electrode and configured to control a bipolar current to flow therethrough in response to a voltage applied between the first electrode and the second electrode.

2. The switching device of claim 1, wherein a level of the bipolar current is adjusted by controlling at least one of a thickness, deposition power, deposition pressure, deposition temperature, and a ratio of sp² and sp³ of the amorphous carbon layer.

3. The switching device of claim 1, wherein the bipolar current comprises:
a first current flowing in a first direction and a second current flowing in a second direction opposite to the first direction depending on voltage polarities between the first electrode and the second electrode.

4. The switching device of claim 3, wherein the first and second currents are the same level in response to the same absolute value of the voltage polarities.

5. A resistance change memory device, comprising:
a first electrode;
a second electrode;
a variable resistance material layer interposed between the first electrode and the second electrode and configured to switch between different resistance states in response to a first voltage applied between both ends of the variable resistance material layer; and
an amorphous carbon layer interposed between the variable resistance material layer and the first electrode or between the variable resistance material layer and the second electrode and configured to control a bipolar current to flow therethrough in response to a second voltage applied between both ends of the amorphous carbon layer.

6. The resistance change memory device of claim 5, wherein a level of the bipolar current is adjusted by at least one of a thickness, deposition power, deposition pressure, deposition temperature, and a ratio of sp² and sp³ of the amorphous carbon layer.

7. The resistance change memory device of claim 5, wherein the bipolar current comprises:
a first current flowing in a first direction and a second current flowing in a second direction opposite to the first direction depending on voltage polarities between the first electrode and the second electrode.

8. The resistance change memory device of claim 7, wherein the first and second currents are the same level in response to the same absolute value of the voltage polarities.

9. The resistance change memory device of claim 5, wherein the variable resistance material layer is configured to switch from a high resistance state to a low resistance state in response to a first polarity of the first voltage and switch from the low resistance state to the high resistance state in response to a second polarity of the first voltage.

10. The resistance change memory device of claim 5, wherein the first electrode includes a plurality of first conductive lines stretched in a first direction,
the second electrode includes a plurality of second conductive lines stretched in a second direction crossing the first direction, and
the variable resistance material layer and the amorphous carbon layer are disposed at each intersection of the first conductive lines and the second conductive lines.

11. The resistance change memory device of claim 10, further comprising:
a plurality of third conductive lines that are stretched in the first direction while being spaced a part from the second conductive lines,
a variable resistance material layer and an amorphous carbon layer interposed between the second conductive lines and the third conductive lines and disposed at each intersection of the second conductive lines and the third conductive lines.

12. The resistance change memory device of claim 5, further comprising:
a metallic intermediate layer that is interposed between the variable resistance material layer and the amorphous carbon layer.

13. The resistance change memory device of claim 5, wherein the variable resistance material layer includes a transition metal oxide or a perovskite-based material.

14. The resistance change memory device of claim 5, wherein the variable resistance material layer includes a stacked structure of an amorphous carbon intermediate layer and a metal-containing layer.

15. The resistance change memory device of claim 14, wherein the metal-containing layer includes a copper layer.

16. The resistance change memory device of claim 5, wherein the first electrode is formed of platinum;
the second electrode is formed of tungsten; and
the variable resistance material layer is formed to have a stacked structure of an amorphous carbon intermediate layer and a metal-containing layer, and
further comprising:
a tungsten layer that is interposed between the variable resistance material layer and the amorphous carbon layer.

17. The resistance change memory device of claim 5, wherein the first electrode is formed of titanium nitride;
the second electrode is formed of titanium nitride; and
the variable resistance material layer includes transition metal oxide.

18. A data processing system, comprising:
a memory; and
a processor configured to process data with the memory,
wherein the memory comprises:
a first electrode;
a second electrode;
a variable resistance material layer interposed between the first electrode and the second electrode and configured to switch between different resistance states in response to a first voltage applied between both ends of the variable resistance material layer; and
an amorphous carbon layer interposed between the variable resistance material layer and the first electrode or between the variable resistance material layer and the second electrode and configured to control a bipolar current to flow therethrough in response to a second voltage applied between both ends of the amorphous carbon layer.

19. The data processing system of claim 18, wherein the amorphous carbon layer is configured to selectively couple the variable resistance material layer with the first electrode or the second electrode by controlling the bipolar current flowing from/to the variable resistance material layer in response to the second voltage.
